(19) United States
(12) Patent Application Publication
(10) Pub. No.: US 2025/0201320 A1
(43) Pub. Date: Jun. 19, 2025

(54) NONVOLATILE MEMORY DEVICES WITH MULTIPLE OPERATION MODES

(71) Applicant: SAMSUNG ELECTRONICS CO., LTD., Suwon-si (KR)

(72) Inventors: Taeyun Lee, Suwon-si (KR); Minjie Choi, Suwon-si (KR)

(21) Appl. No.: 18/784,307

(22) Filed: Jul. 25, 2024

(30) Foreign Application Priority Data
Dec. 15, 2023 (KR) 10-2023-0183646

(51) Int. Cl. G11C 16/34; G11C 16/08; G11C 16/26

(52) U.S. Cl. CPC G11C 16/3459; G11C 16/08; G11C 16/26

(57) ABSTRACT

A method of operating a page buffer included in a non-volatile memory device includes determining a read mode, setting at least one condition among a capacitance of a sensing node of the page buffer, a precharge level of the sensing node, and a trip level of a sensing latch of the page buffer according to the read mode, and performing a program or read operation on a selected cell according to the at least one set condition.

### CROSS-REFERENCE TO RELATED APPLICATION

This application claims priority under 35 U.S.C. § 119 to Korean Patent Application No. 10-2023-0183646, filed on Dec. 15, 2023, in the Korean Intellectual Property Office, the disclosures of which is incorporated by reference herein in its entirety.

### BACKGROUND

Semiconductor memory devices can be broadly divided into volatile memory and non-volatile memory. Volatile memory (for example, DRAM or SRAM) has fast reading and writing speeds, but stored data is lost when the power supply is cut off. On the other hand, non-volatile memory such as NAND flash memory can retain stored data even if the power supply is interrupted. Recently, vertical NAND flash memory devices that are stacked in three dimensions to improve integration have become common.

Vertical NAND flash memory devices form a cell string by stacking memory cells in the vertical direction of the substrate to improve integration. Meanwhile, in vertical NAND flash memory devices, there is a significant difference in the reading environment between a program operation to record data and a read operation to read the written data depending on the number of stacked layers of cells. In For example, the vertical NAND flash memory device may exhibit back pattern dependency characteristics. Even for the same cell, the threshold voltage detected during a read operation to read data appears higher than the threshold voltage during a program verify operation.

The back pattern dependency becomes more noticeable as the number of cell layers increases. To solve this, a method of controlling the size of the sensing current can be used. However, applying this control method is accompanied by a decrease in read performance or program performance.

### SUMMARY

Some implementations according to this disclosure relate to non-volatile memory devices that separate a verification read operation and a data read operation, and methods of operating the same.

Some implementations according to this disclosure relate to a page buffer circuit that separately executes verification read operations accompanying program operations and general data read operations without performance degradation.

According to some implementations, a method of operating a storage device including a plurality of chips includes receiving a write request of stream data, checking a program status or stream queue of each of the plurality of chips in response to the write request, when there is a chip in a ready state with an empty stream queue among the plurality of chips, allocating the stream data to the chip in the ready state, and when there is no chip in a ready state among the plurality of chips, allocating the stream data to a chip with smallest number of stream queues among the plurality of chips.

According to some implementations, a storage device storing multi-stream data, including, a non-volatile memory device including a plurality of chips, and a storage controller configured to allocate a write requested stream to one of the plurality of chips by referring to a program state and stream queue state of each of the plurality of chips, wherein if a chip in a ready state with an empty stream queue exists among the plurality of chips, the storage controller allocates the write requested stream to the chip in the ready state, and if there is no chip in the ready state among the plurality of chips, the storage controller allocates the write requested stream to a chip with smallest number of stream queues among the chips.

According to some implementations, a method of operating a storage device including a plurality of NAND chips includes receiving a write request for stream data, checking a word line offset indicating a programmed word line of each of the plurality of NAND chips, selecting candidate chips to write the stream data according to the word line offset, and programming the stream data into the candidate chips, wherein in the selecting the candidate chips, chips having an unprogrammed first word line and chips having an unprogrammed second word line to be programmed after the first word line are selected as the candidate chips among the plurality of NAND chips, are selected as the candidate chips.

### BRIEF DESCRIPTION OF THE FIGURES

The above and other objects and features of the present disclosure will become apparent by describing in detail examples thereof with reference to the accompanying drawings.

FIG. 1 is a block diagram showing a non-volatile memory device according to some implementations.

FIG. 2 is a circuit diagram showing an example of a structure of a memory block in the cell array of FIG. 1.

FIG. 3 is a diagram illustrating memory cells in a cell string CS of FIG. 2 and their program order.

FIG. 4 is a graph illustrating examples of sensing currents according to some implementations.

FIG. 5 is a block diagram showing an example of a page buffer circuit according to some implementations.

FIG. 6 is a circuit diagram showing an example of a configuration of one of the page buffers of FIG. 5.

FIG. 7 is a diagram showing an example of a page buffer according to some implementations.

FIG. 8 is a circuit diagram showing an example of the sensing node capacitance variation circuit of FIG. 7.

FIG. 9 is a timing chart showing the development trend for each read mode of the sensing node when using a sensing node capacitance variation circuit according to some implementations of the present disclosure.

FIG. 10 is a diagram showing an example of a page buffer according to some implementations.

FIG. 11 is a circuit diagram showing an example of the precharge level variation circuit of FIG. 10.

FIG. 12 is a circuit diagram showing an example of the precharge level variation circuit of FIG. 10.

FIG. 13 is a circuit diagram showing an example of the precharge level variation circuit of FIG. 10.

FIG. 14 is a timing diagram showing the development trend for each read mode of the sensing node when using a precharge level variation circuit according to some implementations.

FIG. 15 is a diagram showing an example of a page buffer according to some implementations.

FIG. 16 is a circuit diagram showing an example of the trip level controller and sensing latch of FIG. 15.

FIG. 17 is a timing diagram showing an example of the effect of varying the trip voltage of the sensing latch when using the trip level controller of FIG. 16.

FIG. 18 is a circuit diagram showing an example of the trip level controller and sensing latch of FIG. 15.

FIG. 19 is a circuit diagram showing an example of the trip level controller and sensing latch of FIG. 15.

FIG. 20 is a graph showing the development time of a sensing node according to the position of the word line.

FIG. 21 is a flowchart showing an operating method of a non-volatile memory device according to some implementations.

### DETAILED DESCRIPTION

The same reference numbers are used in the description and drawings to refer to the same or like parts.

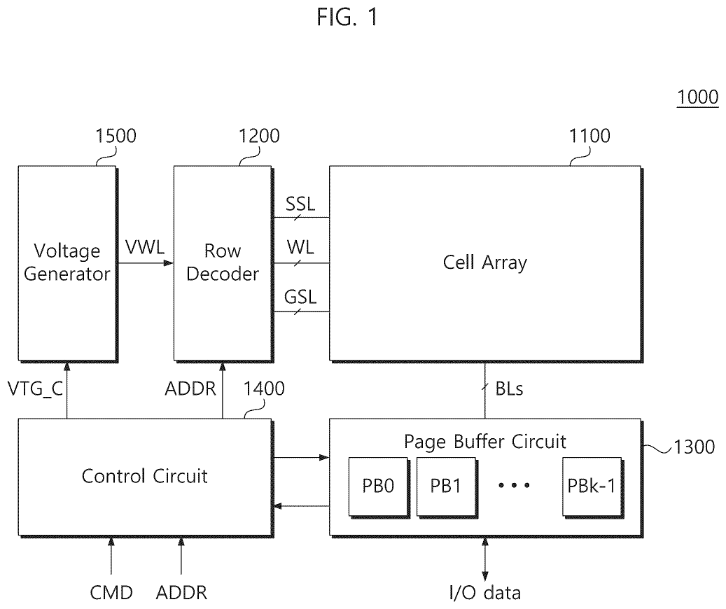

FIG. 1 is a block diagram showing a non-volatile memory device according to some implementations. Referring to FIG. 1, the non-volatile memory device 1000 may include a cell array 1100, a row decoder 1200, a page buffer circuit 1300, a control circuit 1400, and a voltage generator 1500.

The cell array 1100 is connected to the row decoder 1200 through word lines WL or select lines SSL and GSL. The cell array 1100 is connected to the page buffer circuit 1300 through bit lines BLs. The cell array 1100 may include a plurality of NAND cell strings. A channel of each cell string may be formed in a direction perpendicular to the substrate. The cell array 1100 will include a plurality of memory cells forming a cell string. A plurality of memory cells can be programmed, erased, and sensed by voltage provided to bit line BL or word lines WL. The program operation may be performed on a page basis, and the erase operation may be performed on a unit of the block.

As an example, the cell array 1100 may be provided as a three-dimensional memory array. A three-dimensional memory array may be formed monolithically in one or more physical levels of an array of memory cells with an active area disposed over a silicon substrate and circuitry associated with the operation of the memory cells. Circuitry associated with the operation of the memory cells may be located within or on the substrate. The term monolithic means that the layers of each level of the three-dimensional array are deposited directly on top of the layers of lower levels of the three-dimensional array.

In some implementations, a three-dimensional memory array has a vertical orientation and includes vertical NAND strings where at least one memory cell is located above another memory cell. At least one memory cell includes a charge trap layer. Each vertical NAND string may include at least one select transistor located above the memory cells. At least one selection transistor may have the same structure as the memory cells and may be formed monolithically with the memory cells.

The row decoder 1200 may select one of the memory blocks of the cell array 1100 in response to the address ADDR. The row decoder 1200 may select one of the word lines of the selected memory block in response to the address ADDR. The row decoder 1200 delivers a word line voltage VWL corresponding to the operation mode to the word line of the selected memory block. During a program operation, the row decoder 1200 transmits the program voltage and verification voltage to the selected word line and the pass voltage to the unselected word line. During a read operation, the row decoder 1200 transmits a read voltage to the selected word line and a read pass voltage to the unselected word line.

The page buffer circuit 1300 operates as a write driver or a sense amplifier. During the program operation, the page buffer circuit 1300 transfers the bit line voltage corresponding to data to be programmed to the bit lines BLs of the cell array 1100. During a data read operation or the verification read operation, the page buffer circuit 1300 detects data stored in the selected memory cell through bit lines BLs. Here, the data read operation refers to a general read operation that senses data stored in the cell array 1100 based on an external request. Additionally, the operation of sensing whether data has been normally written to the selected memory cell during program operation will be referred to as a verification read operation. The page buffer circuit 1300 stores data detected through bit lines BLs in a data read operation and a verification read operation in a sensing node SO, and converts the level of the sensing node SO into data.

In vertical NAND flash memory, which constitutes a three-dimensional memory array, there may be a significant difference in the reading environment between a program operation to record data and a read operation to read the recorded data depending on the number of stacked cells. For example, the reading environment for each verification read operation and data read operation may be different. For example, vertical NAND flash memory may have back pattern dependency characteristics. For example, considering the first cell to be programmed among stacked memory cells, the remaining cells in the cell string are in an erased state, so the electrical resistance of the channel is low. On the other hand, when the programming of all cells is completed and the data stored in the first programmed cell is read, the electrical resistance of the channel increases because the remaining cells connected in series are all programmed. Thus, during a program operation, the cell threshold voltage appears higher in a data read operation performed after the program is completed than the cell threshold voltage in a verification read operation to determine whether the program was successful.

In some implementations according to the present disclosure, the page buffer circuit (e.g., page buffer circuit 1300) differentially applies the precharge and develop of the sensing node SO, and the operation of latching the level of the sensing node SO, in the data read operation and the verification read operation. For example, the page buffer circuit 1300 can set at least one of the capacitance of the sensing node SO, the precharge level of the sensing node SO, and the trip level of the sensing latch SL differently in each of the data read operation and the verification read operation. For this function, the page buffer circuit 1300 may include a mode selection means (e.g., circuitry) that identifies a data read operation and a verification read operation. Additionally, the page buffer circuit 1300 may include control logic or an additional capacitor that varies the capacitance of the sensing node SO depending on the mode. In some implementations, the page buffer circuit 1300 may include a circuit that can vary the precharge level of the sensing node SO according to the mode. In some implementations, the page buffer circuit 1300 may include a latch circuit or auxiliary circuits that latch the level of the sensing node SO at different trip levels depending on the mode.

Each of the plurality of page buffers PB0 to PBk−1 can program or sense data in selected memory cells. In some implementations, each of the plurality of page buffers PB0 to PBk−1 may include means (e.g., circuitry) for distinguishing between a data read operation and a verification read operation. For example, each of the plurality of page buffers PB0 to PBk−1 may include the above-described mode selection means (e.g., circuitry), a circuit that varies the capacitance of the sensing node SO or the precharge level depending on the mode, and a latch circuit that latches the level of the sensing node SO at different trip levels according to the mode. In some implementations, a plurality of page buffers PB0 to PBk−1 may share means (e.g., circuitry) for distinguishing between a data read operation and a verification read operation.

The control circuit 1400 controls the page buffer circuit 1300, the row decoder 1200, and the voltage generator 1500 in response to a command CMD transmitted from the outside. The control circuit 1400 may control the voltage generator 1500, the page buffer circuit 1300, and the row decoder 1200 to perform program, read, and erase operations on the selected memory cell according to the command CMD. The control circuit 1400 may deliver an address ADDR to the row decoder 1200 and may provide a voltage control signal VTG_C to the voltage generator 1500.

The voltage generator 1500 generates various types of word line voltages VWL to be supplied to each word line under the control of the control circuit 1400 and a voltage that will be supplied to the bulk (e.g., well area) where memory cells are formed. Word line voltages to be supplied to each word line include a program voltage, a pass voltage, and select and non-select read voltages.

The nonvolatile memory device 1000 may include additional components such as an input/output buffer or a mass bit counter. As described above, the nonvolatile memory device 1000 can differentiate the control method of the sensing node SO in each of a data read operation and a verification read operation. Accordingly, it is possible to respond to changes in the sensing environment due to back pattern dependency without adjusting the development time of the sensing node SO. Accordingly, the nonvolatile memory device 1000 can provide high data reliability without deteriorating read or write speed in a vertical NAND flash memory structure.

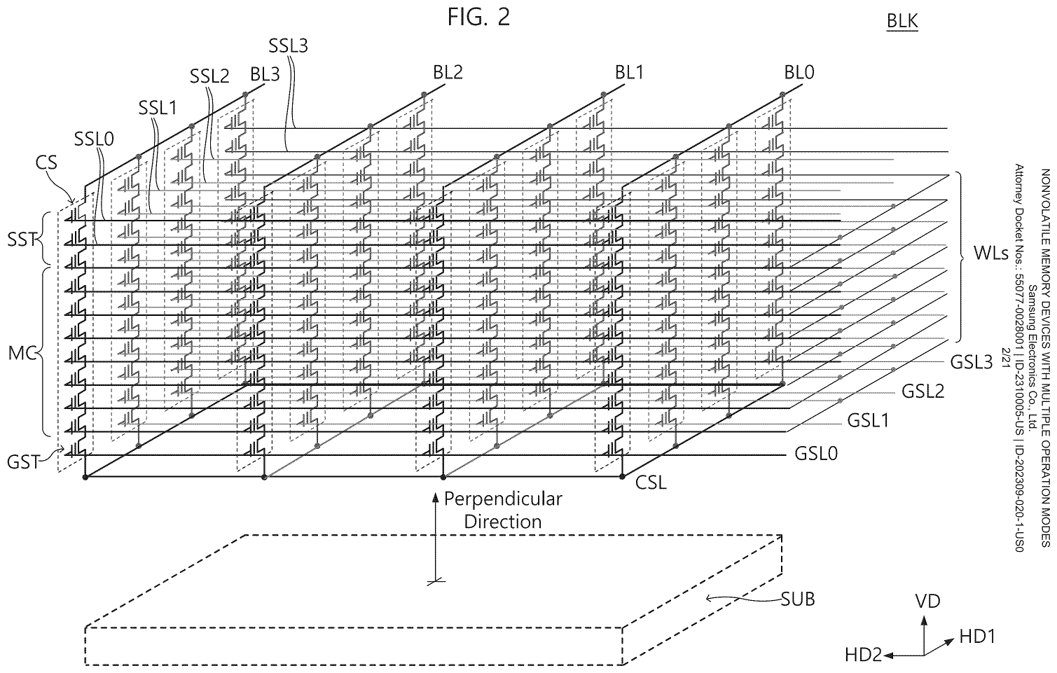

FIG. 2 is a circuit diagram showing an example of a structure of a memory block in the cell array of FIG. 1. Referring to FIG. 2, cell strings CS are formed between the bit lines BL0, BL1, BL2, and BL3 and the common source line CSL to form the memory block BLK.

A plurality of cell strings are formed between the bit line BL0 and the common source line CSL. The string select transistor SST of the cell strings CS is connected to the corresponding bit line (BL). The ground select transistor GST of the cell strings CS is connected to the common source line CSL. Memory cells MC are provided between the string select transistor SST and the ground select transistor GST of the cell string CS.

Each of the cell strings CS includes a ground select transistor GST. Ground selection transistor GST included in the cell strings CS may be controlled by the ground selection line GSL. Alternatively, although not shown, cell strings CS corresponding to each row may be controlled by different ground selection lines.

Above, the circuit structure of memory cells included in one memory block BLK is described. However, the circuit structure of the illustrated memory block is a simplified structure for convenience of explanation, and the actual memory block is not limited to the illustrated example. In other words, it will be well understood that one physical block may include more semiconductor layers, bit lines BLs, and string select lines SSLs, or have a different architecture from that illustrated.

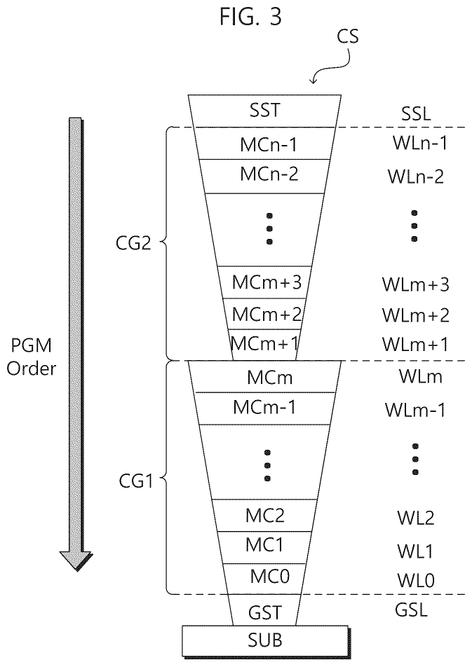

FIG. 3 is a diagram illustrating memory cells of the cell string CS of FIG. 2 and their program order. In the example of a FIG. 3, in the cell string CS, the memory cells are programmed in the order from memory cells located farthest from the substrate SUB to memory cells closer to the substrate SUB. However, the program order may be reversed depending on various purposes.

Here, one cell string CS may include a plurality of memory cells (MC0 to MCn−1, where n is a natural number greater than 1). For example, the memory cell MC0 is the memory cell closest to the substrate, and the memory cell MCn−1 is the memory cell furthest from the substrate.

The cell string CS may include two cell groups CG1 and CG2 in which the size of the memory cells increases as the distance from the substrate SUB increases. This type is a method of forming a greater number of memory cells in one cell string CS to increase the integration of vertical NAND flash memory. The first cell group CG1 may include memory cells MC0 to MCm whose sizes increase in order. The second cell group CG2 may include memory cells MCm+1 to MCn−1 whose sizes increase in order. Starting with the memory cell MCn−1 located at a relatively long distance from the substrate SUB, the memory cell MC0 may be programmed last.

According to the above-described cell string type, the number ‘n’ of memory cells MC0 to MCn−1 provided by one cell string CS may increase. However, in this structure, depending on the number of stacked cells, a large difference occurs in the reading environment of the data read operation and the verification read operation due to back pattern dependency. For example, assume that the memory cell MCn−1 is programmed first among the stacked memory cells during a program operation. Then, since the remaining cells MC0 to MCn−2 of the cell string CS are in an erased state (or on-cell state), the electrical resistance of the channel will be relatively small.

On the other hand, if the data stored in the programmed cell MCn−1 is read for the first time after the programming of all cells MC0-MCn−1 is completed, the remaining cells MC0-MCn−2 connected in series are all in programmed state. Of course, among the remaining cells MC0 to MCn−2, some cells may be programmed in an on cell state, but the electrical resistance of the channel increases on average due to the memory cells being in a programmed state. Accordingly, the cell threshold voltage detected during a data read operation performed after the program is completed may appear higher than the cell threshold voltage detected during a verification read operation that occurs during a program operation.

According to some implementations of the present disclosure, technology is provided to distinguish between a data read operation and a verification read operation in the page buffer circuit 1300 to vary the capacitance or precharge level of the sensing node SO, or the trip level of the sensing latch. In this case, the size of the sensing current corresponding to the level change of the sensing node SO can be differentially applied to each of the data read operation and verification read operation. This process makes it possible to compensate for the back pattern dependency of the non-volatile memory device 1000 without performance degradation that occurs when using a control method that adjusts the development time of the sensing node SO.

In addition, technology for varying the capacitance or precharge level of the sensing node SO, or the trip level of the sensing latch can be applied not only to the read mode but also to changes in other conditions. For example, the capacitance or precharge level of the sensing node SO, or the trip level of the sensing latch can be varied depending on at least one of the location, operating temperature, and wear level of the technology cell. Here, the location of the cell may vary depending on the word line, block, MAT, and the chip containing the cell.

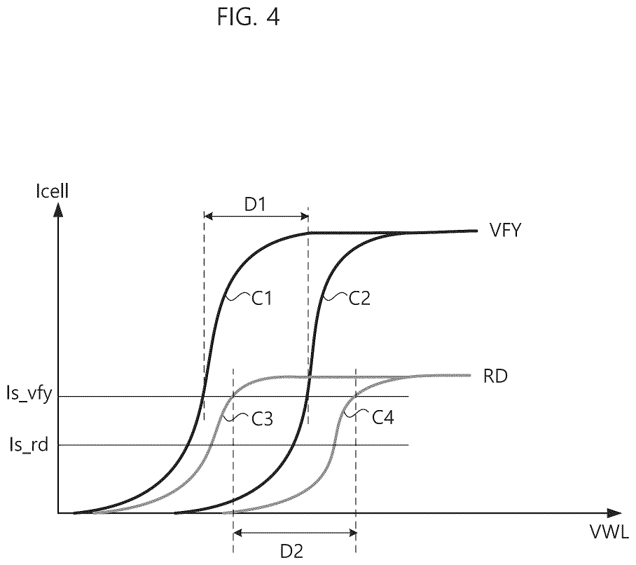

FIG. 4 is a graph illustrating the sensing current of memory cells that are programmed first in a cell string. FIG. 4 shows the difference in sensing current according to the data read operation and the verification read operation mode due to the back pattern dependency of memory cells connected to the same word line (e.g., WLn−1 in FIG. 3).

First, the curves C1 and C2 show the characteristics of the cell current Icell immediately after the memory cells of the word line WLn−1 are programmed. At this time, the memory cells connected to the word lines WL0 to WLn−2 are in an erased state before being programmed. For example, the curves C1 and C2 can show cell currents in a state in which the memory cells of the word line WLn−1 are not affected by the back pattern dependency. According to the curve C1, it shows the characteristics of a cell with a slow programming speed (or slow cell) among the memory cells MCn−1 that are programmed first. The curve C2 shows the cell current Icell of a cell with a high program speed (or fast cell) among the memory cells of the word line WLn−1. According to the curves C1 and C2, it can be seen that even if connected to the same word line WLn−1, a difference in threshold voltage distribution may occur immediately after programming depending on the characteristics of the cell.

The curves C3 and C4 show the characteristics of the cell current Icell of the memory cells of the word line WLn−1 after all word lines WL0 to WLn−1 have been programmed or in read operation mode. At this time, the memory cells connected to the word lines WL0 to WLn−2 exist in a programmed state. For example, the curves C3 and C4 can show the cell current Icell when the memory cells of the word line WLn−1 are affected by back pattern dependency. According to the curve C3, among the memory cells MCn−1, cells with a slow program speed (or slow cells) can be seen as having back pattern dependency reflected. The curve C4 corresponds to a cell current Icell that reflects the back pattern dependency of a cell with a fast program speed (or fast cell) among the memory cells of the word line WLn−1. However, according to the curves C3 and C4 during a data read operation, the cell current Icell that can be reached even with an increase in the word line voltage VWL is smaller than for the curves C1 and C2.

In the graph of FIG. 4, based on the first sensing current Is_vfy, the threshold voltage distribution or difference in characteristics (e.g., cell resistance) between cells during a program operation and a data read operation are shown as distribution widths (D1 and D2), respectively. Under the condition of the first sensing current Is_vfy for measuring the dispersion width, the memory cells of the word line WLn−1 will display the first dispersion width D1 during a program operation. On the other hand, under the condition of the first sensing current Is_vfy during the read operation, the memory cells of the word line WLn−1 will exhibit the second dispersion width D2 according to the back pattern dependency. It can be seen that the second distribution width D2 during the read operation is wider than the first distribution width D1 during the program operation.

According to some implementations according to the present disclosure, a page buffer circuit (e.g., page buffer circuit 1300) is configured to differentiate the sensing current according to the read mode based on the above-described back pattern dependency. For example, the page buffer circuit 1300 can be set so that the first sensing current Is_vfy flows during a verification read operation VFY, and the second sensing current Is_rd flows during a data read operation RD. In some implementations, the first sensing current Is_vfy applied during the verification read operation VFY can be expressed as Equation 1 below.

$$Is\_vfy = \frac{Cso\_vfy ( Vprch\_vfy - Vtrip\_vfy )}{Tso\_dev} \qquad [ Equation 1 ]$$

Here, ‘Tso_dev’ is the development time of the sensing node, ‘Cso_vfy’ is the capacitance of the sensing node SO set during the verification read operation, ‘Vprch_vfy’ is the precharge level of the sensing node SO during the verification read operation, and ‘Vtrip_vfy’ represents the trip voltage for latching the sensing node SO during the verification read operation.

In addition, in some implementations, the second sensing current Is_rd applied during the data read operation RD can be expressed as Equation 2 below.

$$Is\_rd = \frac{Cso\_rd ( Vprch\_rd - Vtrip\_rd )}{Tso\_dev} \qquad [ Equation 2 ]$$

Here, ‘Tso_dev’ is the development time of the sensing node SO, ‘Cso_rd’ is the capacitance of the sensing node SO set during the data read operation, and ‘Vprch_rd’ is the precharge of the sensing node SO during the data read operation. The level, ‘Vtrip_rd’, represents the trip voltage for latching the sensing node SO during the data read operation.

According to the above-mentioned Equation 1 and Equation 2, in order to overcome the back pattern dependency, it is possible to differentiate the sensing current without adjusting the development time Tso_dev of the sensing node SO during the data read operation and verification read operation. For example, it can be seen that it is possible to distinguish the sensing current according to the read mode by adjusting the capacitance of the sensing node SO, the precharge level of the sensing node SO, and the trip voltage to latch the sensing node SO.

To provide these features, the page buffer circuit 1300 can vary at least one of the capacitance of the sensing node SO, the precharge level of the sensing node SO, and the trip level of the sensing latch, e.g., rather than adjusting the develop time Tso_dev. The specific configuration and operation of the page buffer circuit 1300 will be described in detail through drawings described later.

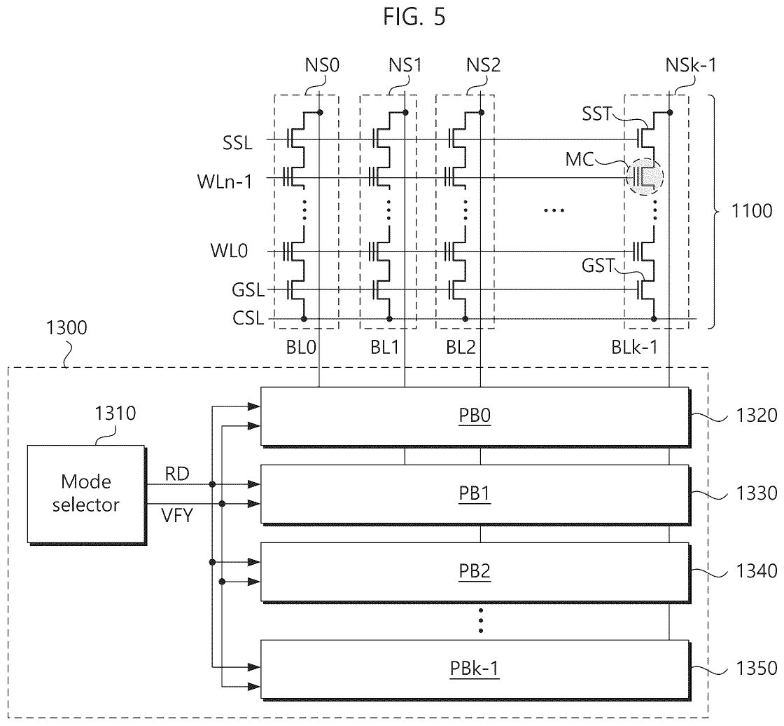

FIG. 5 is a block diagram showing a page buffer circuit that varies the processing method of the sensing current according to the read mode. Referring to FIG. 5, the page buffer circuit 1300 may include a mode selector 1310 and a plurality of page buffers (PB0 to PBk−1, 1320 to 1350).

Each of the plurality of NAND cell strings NS0 to NSk−1 may include a ground selection transistor GST connected to the ground selection line GSL. And each of the NAND cell strings NS0 to NSk−1 includes a plurality of memory cells MC connected to a plurality of word lines WL0 to WLn−1, and a string selection transistor SST connected to a string selection line SSL. And the ground select transistor GST, memory cell MC, and string select transistor SST may be connected to each other in series.

The page buffer circuit 1300 may include a mode selector 1310. The mode selector 1310 may identify whether the read mode is a data read operation RD or a verification read operation VFY. For example, the mode selector 1310 may determine the read mode in which the page buffer circuit 1300 should operate by referring to decoded commands or control signals provided from the control circuit 1400. The mode selector 1310 may be implemented as an internal component of the page buffer circuit 1300 or an internal component of the control circuit 1400.

The page buffer circuit 1300 may include a plurality of page buffers PB0 to PBk−1. The first page buffer PB0 is connected to the first NAND cell string NS0 through the first bit line BL0, and the k-th page buffer PBk−1 is connected to the first NAND cell string NSk−1 through the k-th bit line BLk−1. Here, ‘k’ is a positive integer. For example, ‘k’ may be 8, and the page buffer circuit 1300 may have a structure in which 8 page buffers PB0 to PB7 are arranged in a row. As another example, the page buffer circuit 1300 may have four rows of page buffers PB0 to PB3 and page buffers PB4 to PB7 arranged in a row symmetrically with respect to a page buffer decoder.

Each of the plurality of page buffers PB0 to PBk−1 can program or sense data in selected memory cells. Each of the plurality of page buffers PB0 to PBk−1 can differentiate at least one of the capacitance of the sensing node SO, the precharge level of the sensing node SO, and the trip level of the sensing latch in read mode RD and VFY. To provide these features, each of the plurality of page buffers PB0 to PBk−1 may include control logic or an additional capacitor that varies the capacitance of the sensing node SO depending on the read mode. In some implementations, the page buffer circuit 1300 may include a circuit that can vary the precharge level of the sensing node SO according to the read mode. In some implementations, the page buffer circuit 1300 may include a latch circuit or auxiliary circuits that latch the level of the sensing node SO at different trip levels depending on the read mode.

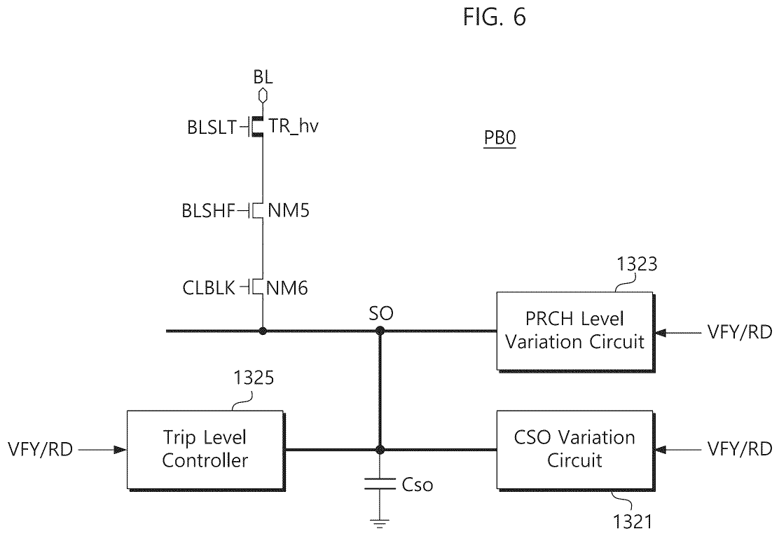

FIG. 6 is a circuit diagram showing an example of a configuration of one of the page buffers of FIG. 5. Referring to FIG. 6, the page buffer PB0 includes a sensing node capacitance variation circuit 1321, a precharge level variation circuit 1323, and a trip level controller 1325.

The page buffer PB0 may include a bit line select transistor TR_hv connected to the bit line BL and driven by the bit line select signal BLSLT. The bit line selection transistor TR_hv may be implemented as a high voltage transistor, and accordingly, the bit line selection transistor TR_hv may be disposed in a high voltage region. Additionally, NMOS transistors NM5 and NM6 and control signals BLSHF and CLBLK may be provided to connect the bit line BL and the sensing node SO.

The sensing node capacitance variation circuit 1321 can vary the capacitance of or at the sensing node SO depending on the read mode (or operation mode). For example, the sensing node capacitance variation circuit 1321 may set the sensing node capacitance Cso_rd in the data read operation RD and the sensing node capacitance Cso_vfy in the verification read operation VFY differently.

The precharge level variation circuit 1323 can vary the level of the precharge voltage of the sensing node SO according to the read mode (or operation mode). For example, the precharge level variation circuit 1323 controls the precharge voltage of the sensing node SO during the data read operation RD and the verification read operation VFY, differently, e.g., to Vprch_vfy or Vprch_rd.

The trip level controller 1325 can vary the trip voltage of the sensing latch according to the read mode (or operation mode). The sensing latch latches the sensed data by latching the developed voltage of the precharged sensing node SO. The trip level controller 1325 may vary the trip level, which is a reference level for latching the developed voltage of the sensing node SO, depending on the read mode, e.g., to Vtrip_vfy or Vtrip_rd.

The page buffer PB0 may use at least one of the sensing node capacitance variation circuit 1321, the precharge level variation circuit 1323, and the trip level controller 1325 depending on the read mode (or operation mode). The page buffer PB0 varies at least one of the capacitance of the sensing node SO, the precharge level, or the trip level of the sensing latch (e.g., without adjusting the development time of the sensing node SO), thereby compensating for back pattern dependency. Accordingly, the nonvolatile memory device 1000 can provide high data reliability without reducing program speed or read speed.

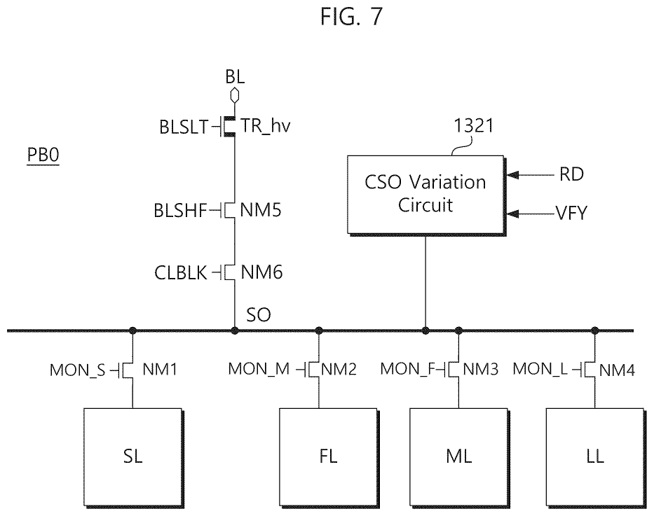

FIG. 7 is a diagram showing the structure of an example of a page buffer, e.g., PB0. Referring to FIG. 7, the page buffer PB0 includes a sensing node capacitance variation circuit 1321, a sensing latch SL, a forcing latch FL, an upper bit latch ML, and a lower bit latch LL.

The sensing node capacitance variation circuit 1321 can vary the capacitance of the sensing node SO depending on the operation mode. For example, the sensing node capacitance variation circuit 1321 may set the sensing node capacitance during a data read operation RD and a verification read operation VFY to be different. For example, the sensing node capacitance variation circuit 1321 may provide additional capacitance to a default capacitance Cso of the sensing node SO during a verification read operation VFY. And, the sensing node capacitance variation circuit 1321 can control the capacitance of the sensing node SO to maintain the default capacitance Cso during a data read operation RD.

The sensing latch SL may store the data stored in the memory cell or the sensing result of the threshold voltage of the memory cell during a data read operation RD or verification read operation VFY. Additionally, the sensing latch SL may be used to apply a program bit line voltage or a program inhibit voltage to the bit line BL during a program operation. The forcing latch FL can be used as a bit line bias means to improve threshold voltage distribution during program operation. The upper bit latch ML and lower bit latch LL can be used to store externally input data during program operations.

By using the above-described sensing node capacitance variation circuit 1321, the page buffer PB0 can vary the capacitance of the sensing node according to the read (or operation) mode RD and VFY. Accordingly, the back pattern dependency according to the read mode can be compensated for, e.g., without changing the development time Tso_dev of the sensing node SO. Variable development time Tso_dev of the sensing node SO during sensing operation may mean a decrease in the speed of reading or program operation. Due to the sensing node capacitance variation circuit 1321 of the page buffer PB0, the nonvolatile memory device 1000 can, in some implementations, provide high data reliability without a decrease in program speed or read speed.

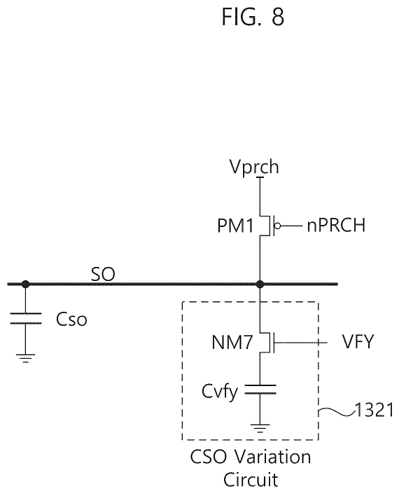

FIG. 8 is a circuit diagram showing an example of the sensing node capacitance variation circuit of FIG. 7. Referring to FIG. 8, the sensing node capacitance variation circuit 1321 may include a verification capacitor Cvfy that can be connected to or disconnected from the sensing node SO.

The sensing node capacitance variation circuit 1321 may include an NMOS transistor NM7 that is turned on in the verification read operation. The NMOS transistor NM7 separates the verification capacitor Cvfy from the sensing node SO during a data read operation. For example, during a data read operation, the read mode signal VFY may be provided at a low level L, and the NMOS transistor NM7 may be turned off. Then, during a data read operation, the total capacitance of the sensing node SO will be set to the default capacitance Cso. On the other hand, the NMOS transistor NM7 connects the verification capacitor Cvfy to the sensing node SO during the verification read operation. For example, during the verification read operation, the read mode signal VFY may be provided at a high level H, and the NMOS transistor NM7 may be turned on. Then, the total capacitance of the sensing node SO increases to the total value of the default capacitance Cso of the sensing node SO and the verification capacitor Cvfy connected in parallel.

During a data read operation or verification read operation, the sensing node SO is precharged and developed under variable capacitance conditions. When the precharge control signal nPRCH is activated to a low level in a sensing node precharge interval of the data read operation, the PMOS transistor PM1 is turned on. Then, the sensing node SO is charged with the precharge voltage Vprch under the default capacitance Cso condition. And, in the sensing node development interval, the sensing node SO is developed based on the amount of charge charged in the default capacitance Cso.

When the precharge control signal nPRCH is activated to a low level in a sensing node precharge interval of the verification read operation, the PMOS transistor PM1 is turned on. Then, the sensing node SO is charged with the precharge voltage Vprch under the condition of increased sensing node capacitance Cso+Cvfy. And, in the sensing node development interval, the sensing node SO is developed based on the charge charged in the increased sensing node capacitance Cso+Cvfy. Accordingly, in some implementations, the development speed of the precharge voltage Vprch may be reduced, e.g., rather than the development speed of the data read operation.

The method of adding the verification capacitor Cvfy can be implemented in various ways. For example, during the verification read operation, the verification capacitor Cvfy may be connected to ground by using a switch to connect the unused metal line or active area around the sensing node SO to ground. And, during a data read operation, the capacitance of the sensing node SO can be restored to the default capacitance Cso by floating the metal line or active area described above. The method of adding the verification capacitor Cvfy is not limited to the examples described above, and various methods and corresponding circuits are within the scope of this disclosure.

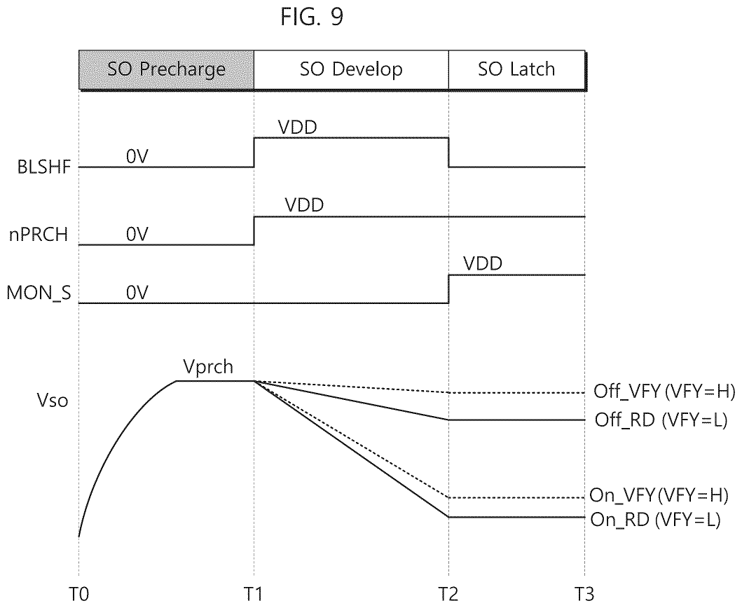

FIG. 9 is a timing chart showing the development trend for each read mode of the sensing node when using a sensing node capacitance variation circuit. Referring to FIG. 9, the development speed of the precharged voltage of the sensing node SO may vary depending on the connection of the verification capacitor Cvfy according to the read mode.

At T0, the precharge operation of the sensing node SO begins. To precharge the sensing node SO, the precharge control signal nPRCH is activated at a low level (e.g., 0V). Then, the PMOS transistor PM1 will be turned on, and the voltage of the sensing node SO will rise to the precharge voltage Vprch level. At this time, the control signals BLSHF and MON_S may be provided at a level of 0V.

At T1, the development process of the sensing node SO is underway. For development of the sensing node SO, the control signal BLSHF connecting the bit line BL and the sensing node SO transitions to the high level or the power supply voltage VDD. And the precharge control signal nPRCH is deactivated at a high level (e.g., VDD). As the precharge control signal nPRCH is deactivated, the PMOS transistor PM1 is turned off. Then, the sensing node SO precharged with the precharge voltage Vprch is developed according to the level of the bit line BL.

As is shown, the development speed of the precharge voltage for an off cell in the verification read mode (VFY=H) is slower than the development speed for the off cell in the data read mode (VFY=L). This is due to the addition of a verification capacitor Cvfy in verification read mode (VFY=H). In addition, it can be seen that the development speed of the precharge voltage for on-cells in verification read mode (VFY=H) is slower than the development speed for on-cells in data read mode (VFY=L). This effect is because a verification capacitor Cvfy is added to the sensing node SO in verification read mode (VFY=H).

At time T2, a latch operation of the sensing latch SL for the developed sensing node SO is performed. For this function, the control signal MON_S for connecting the sensing latch SL and the sensing node SO will transition to high level. Although not shown, the reset signal RST that sets the sensing latch SL will be activated according to the development result of the sensing node SO.

According to the above description, the sensing node SO can confirm that the development speed of the precharged voltage varies depending on the connection of the verification capacitor Cvfy according to the read mode. As a result, it is possible to separate the data read mode and verification read mode by disconnecting and connecting the verification capacitor Cvfy, e.g., without adjusting the development time of the sensing node.

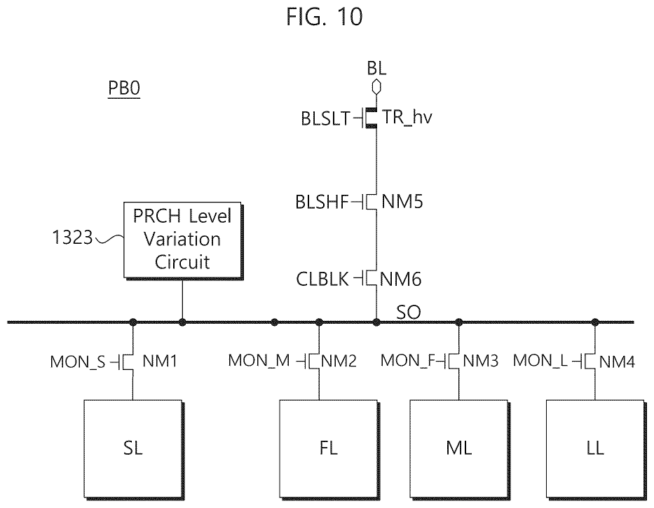

FIG. 10 is a diagram showing the structure of a page buffer according to some implementations. Referring to FIG. 10, the page buffer PB0 includes a precharge level variation circuit 1323, a sensing latch SL, a forcing latch FL, a upper bit latch ML, and an optional lower bit latch LL.

The precharge level variation circuit 1323 can vary the level of the precharge voltage of the sensing node SO according to the read mode. For example, the precharge level variation circuit 1323 may set differently the precharge voltage Vprch of the sensing node SO during the data read operation RD and during the verification read operation VFY. For this function, the precharge level variation circuit 1323 may use at least one of a circuit that selects a different level of precharge voltage, a voltage clamping circuit, or a precharge voltage boosting circuit.

The configuration and functions of the sensing latch SL, forcing latch FL, upper bit latch ML, and lower bit latch LL are substantially the same as those in FIG. 7 described above. Therefore, detailed descriptions of these will be omitted.

By using the above-described precharge level variation circuit 1323, the page buffer PB0 can vary the precharge level of the sensing node according to the read mode RD/VFY. Therefore, the back pattern dependency according to the read mode can be compensated for without changing the development time Tso_dev of the sensing node SO.

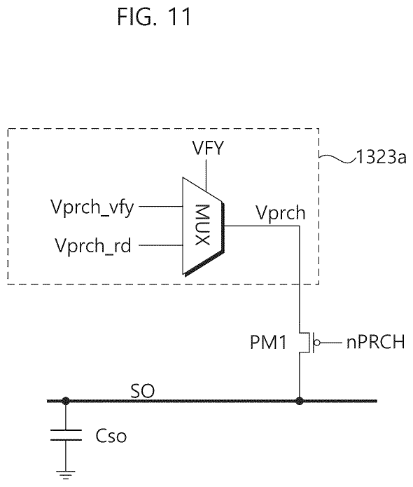

FIG. 11 is a circuit diagram showing an example of the precharge level variation circuit of FIG. 10. Referring to FIG. 11, the precharge level variation circuit 1323a may be configured as a selection circuit MUX that selects the precharge voltage Vprch for precharging the sensing node SO according to the read mode.

The precharge level variation circuit 1323a may include the selection circuit MUX that selects one of the different precharge voltages Vprch_vfy and Vprch_rd according to the read mode signal VFY. The selection circuit MUX may select the first precharge voltage Vprch_vfy in response to the high level of the read mode signal VFY. Additionally, the selection circuit MUX may select the second precharge voltage Vprch_rd in response to the low level of the read mode signal VFY. In the sensing node precharge interval, one of the precharge voltages Vprch_vfy and Vprch_rd selected by the selection circuit MUX is provided as the precharge voltage Vprch. Here, the second precharge voltage Vprch_rd may be at a lower level than the first precharge voltage Vprch_vfy.

Then, when the precharge control signal nPRCH is activated to a low level, the PMOS transistor PM1 is turned on. Then, the sensing node SO is charged with the precharge voltage Vprch under the default capacitance Cso condition of the sensing node. And, in the sensing node development interval, the sensing node SO will be developed based on the charge charged in the default capacitance Cso.

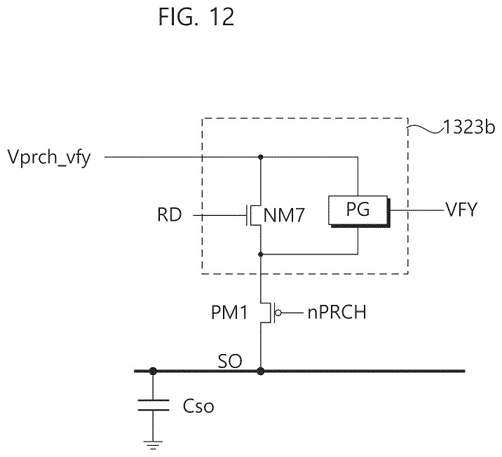

FIG. 12 is a circuit diagram showing another example of the precharge level variation circuit of FIG. 10. Referring to FIG. 12, the precharge level variation circuit 1323b includes a clamping circuit that selectively clamps the first precharge voltage Vprch_vfy for precharging the sensing node SO according to the read mode signals VFY/RD.

When the verification read mode signal VFY is activated and the data read mode signal RD is deactivated, the precharge level variation circuit 1323b transfers the first precharge voltage Vprch_vfy to the source side of the PMOS transistor PM1 without changing the level. In order to transfer the first precharge voltage Vprch_vfy without changing the level, the precharge level variation circuit 1323b may include a pass gate PG using complementary pass transistor logic CPTL.

In addition, when the verification read mode signal VFY is inactivated and the data read mode signal RD is activated, the precharge level variation circuit 1323b clamps the first precharge voltage Vprch_vfy and transfers it to the source side of the PMOS transistor PM1. To clamp the first precharge voltage Vprch_vfy, the precharge level variation circuit 1323b may include a clamping transistor NM7. Depending on the level of the data read mode signal RD transmitted to the gate of the clamping transistor NM7, the first precharge voltage Vprch_vfy is clamped to the second precharge voltage Vprch_rd and is applied to the source terminal of the PMOS transistor PM1. Accordingly, one of the different precharge voltages Vprch_vfy and Vprch_rd is provided as the precharge voltage Vprch according to the read mode signals VFY/RD.

When the precharge control signal nPRCH is activated to a low level, the PMOS transistor PM1 is turned on, and the sensing node SO is charged with the precharge voltage Vprch under the default capacitance Cso condition of the sensing node. And in the sensing node development interval, the sensing node SO will be developed based on the charge charged in the default capacitance Cso.

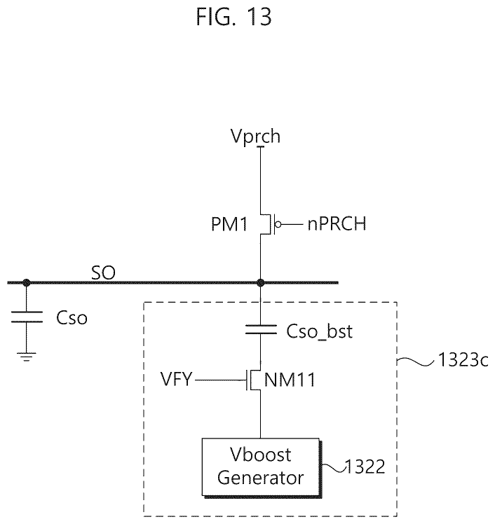

FIG. 13 is a circuit diagram showing another example of the precharge level variation circuit of FIG. 10. Referring to FIG. 13, the precharge level variation circuit 1323c may selectively boost the precharged sensing node SO in response to the read mode signal VFY. The precharge level variation circuit 1323c may include a boosting voltage generator 1322, a boosting transistor NM11, and a boosting capacitor Cso_bst.

The precharge level variation circuit 1323c is deactivated during a data read operation in which the verification read mode signal VFY is deactivated. For example, during the data read operation, the boosting transistor NM11 is turned off, and application of the boosting voltage to the sensing node SO is blocked. During the data read operation, when the precharge control signal nPRCH is activated to a low level, the PMOS transistor PM1 is turned on, and the sensing node SO is charged with the precharge voltage Vprch under the default capacitance Cso condition of the sensing node. And in the sensing node development interval, the sensing node SO will be developed based on the charge charged in the default capacitance Cso.

On the other hand, the precharge level variation circuit 1323c is activated during a verification read operation in which the verification read mode signal VFY is activated. For example, when the precharge control signal nPRCH is activated to a low level during the verification read operation, the PMOS transistor PM1 is turned on. Subsequently, the sensing node SO is charged with the precharge voltage Vprch under the default capacitance Cso condition of the sensing node. And in response to activation of the verify read mode signal VFY, the boosting transistor NM11 is turned on. Then, the boosting voltage generated by the boosting voltage generator 1322 will be transmitted to the boosting capacitor Cso_bst. Accordingly, the sensing node SO, which is primarily charged to the precharge voltage Vprch level, is boosted by the boosting voltage Vbst. Boosting voltage generator 1322 may be provided using any of a variety of voltage generator structures, such as a voltage divider or charge pump.

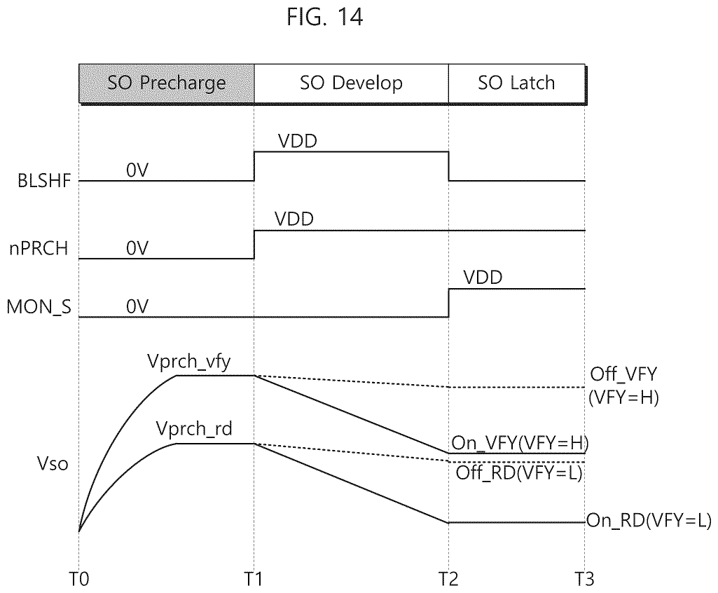

FIG. 14 is a timing diagram showing the development trend for each read mode of the sensing node when using the precharge level variation circuit of FIG. 10. Referring to FIG. 14, as the precharge level of the sensing node SO changes according to the read mode, the development characteristics of the precharged voltage of the sensing node SO may vary.

At T0, the sensing node SO is precharged. To precharge the sensing node SO, the precharge control signal nPRCH is activated at a low level (e.g., 0V). Then, the PMOS transistor PM1 is turned on, and the sensing node SO rises to one of the precharge voltages Vprch_vfy and Vprch_rd. At this time, during the verification read operation, the sensing node SO is charged with the first precharge voltage Vprch_vfy. On the other hand, during a data read operation, the sensing node SO is charged with a second precharge voltage Vprch_rd that is relatively lower than the first precharge voltage Vprch_vfy. In the precharge interval of the sensing node SO, the control signals BLSHF and MON_S may be 0V.

At T1, development of the sensing node SO is in progress. For development of the sensing node SO, the control signal BLSHF connecting the bit line BL and the sensing node SO transitions to the high level or the power supply voltage VDD level. And the precharge control signal nPRCH is deactivated at a high level (or VDD). Then, the PMOS transistor PM1 is turned off. And, the sensing node SO charged with one of the precharge voltages Vprch_vfy and Vprch_rd is developed according to the level of the bit line BL.

As shown, the voltage drop characteristics due to the development of the sensing node SO for on-cell and off-cell in verification read mode (VFY=H) are differentiated from the voltage drop characteristics in data read mode (VFY=L). This is due to the fact that the precharge level Vprch_vfy of the sensing node SO in the verification read mode (VFY=H) is set differently from the precharge level Vprch_rd in the data read mode.

At time T2, a latch operation of the sensing latch SL for the sensing node SO will be performed. For example, the control signal MON_S for connecting the sensing latch SL and the sensing node SO will transition to high level. A reset signal RST that sets the sensing latch SL may be activated according to the development result of the sensing node SO.

According to the above description, the sensing node SO can be charged at different precharge levels depending on the read mode by the precharge level variation circuit 1323. Therefore, the data read mode and verification read mode can be differentiated by changing the precharge level, e.g., without adjusting the development time of the sensing node SO.

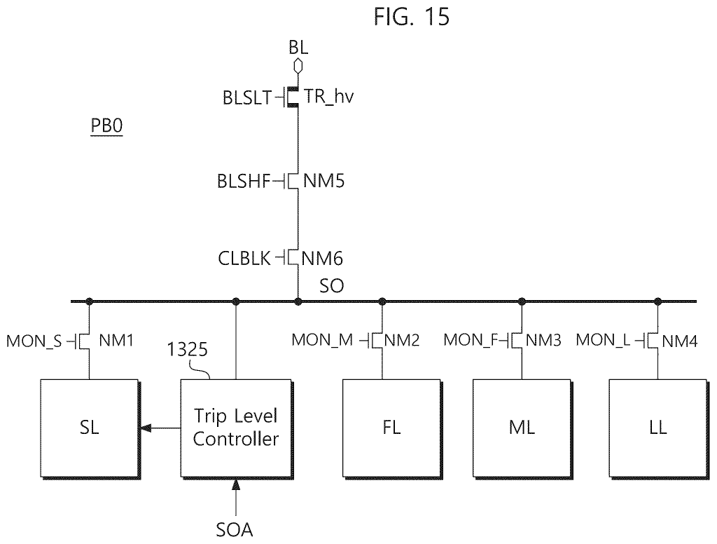

FIG. 15 is a diagram showing an example of a page buffer according to some implementations of the present disclosure. Referring to FIG. 15, the page buffer PB0 may include a trip level controller 1325, a sensing latch SL, a forcing latch FL, an upper bit latch ML, and a lower bit latch LL.

The trip level controller 1325 can vary the level of the trip voltage of the sensing latch SL according to the read mode. For example, the trip level controller 1325 sets the trip voltage Vtrip of the sensing latch SL differently during the data read operation RD and the verification read operation VFY. The trip level controller 1325 may include an element or circuit to set the trip voltage Vtrip at different levels according to the read mode.

In some implementations, the sensing latch SL may be configured as an inverter-type latch in which the input and output of two inverters are connected. In this case, the sensing latch SL generates a data latch based on racing between the PMOS transistor and the NMOS transistor. In some implementations, the sensing latch SL may be implemented as a tri-state latch. In this case, the sensing latch SL latches data only by the operation of the NMOS transistor. This example will be explained in detail through the drawings described later.

The configuration and functions of the forcing latch FL, the upper bit latch ML, and the lower bit latch LL are substantially the same as those in FIG. 7 described above. Therefore, detailed descriptions of these will be omitted.

By using the above-described trip level controller 1325, the page buffer PB0 can vary the level of the trip voltage of the sensing latch SL according to the read mode. Therefore, it is possible to compensate for the back pattern dependency according to the read mode, e.g., without changing the development time Tso_dev of the sensing node SO.

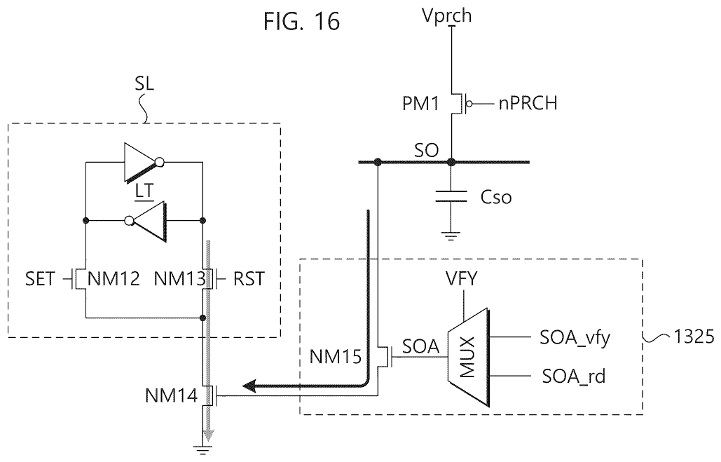

FIG. 16 is a circuit diagram showing an example of the trip level controller and sensing latch of FIG. 15. Referring to FIG. 16, the trip level controller 1325 includes an NMOS transistor NM15 that transfers the develop level of the sensing node SO to the NMOS transistor NM14 according to the read mode signal (VFY or RD), and a selection circuit MUX (e.g., a multiplexer).

The trip level controller 1325 can vary the trip voltage of the sensing latch according to the operation mode. The sensing latch latches the sensed data by latching the develop voltage Vdvl of the precharged sensing node SO. The trip level controller 1325 may vary the trip level, which is a reference level for latching the developed voltage of the sensing node SO, according to the operation mode.

The trip level controller 1325 provides a first level SOA_vfy during a verification read operation and a second level SOA_rd lower than the first level SOA_vfy during a data read operation as a control signal SOA to the gate of the NMOS transistor NM15. Then, the NMOS transistor NM15 is turned on to pass the develop voltage Vdvl of the sensing node SO to the gate of the NMOS transistor NM14. At the same time, the NMOS transistor NM14 for grounding the latch is turned on. And then, the latch LT is tripped when the reset signal RST transitions to a high level. This trip mechanism will be equally applied to data read operations. However, the turn-on time of the NMOS transistor NM15 becomes faster in the verification read operation in which the first level SOA_vfy is transmitted to the gate the NMOS transistor NM15. As a result, the trip voltage of the latch LT is lowered during the verification read operation.

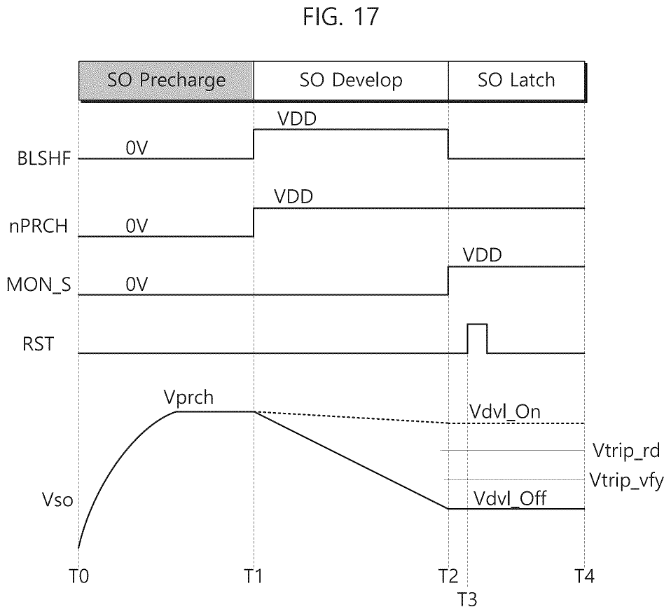

FIG. 17 is a timing diagram showing the effect of varying the trip voltage of the sensing latch when using the trip level controller of FIG. 16. Referring to FIG. 17, the effect of varying the trip voltage of the sensing latch SL occurs according to the level of the control signal SOA for transmitting the develop voltage Vdvl.

At T0, regardless of the read mode, the sensing node SO is charged with the precharge voltage Vprch. To precharge the sensing node SO, the precharge control signal nPRCH is activated at a low level (or 0V). Then, the PMOS transistor PM1 is turned on, and the voltage of the sensing node SO will rise to the precharge voltage Vprch.

At T1, development of the sensing node SO is in progress. For development of the sensing node SO, the control signal BLSHF connecting the bit line BL and the sensing node SO transitions to the high level or the power supply voltage VDD level. And the precharge control signal nPRCH is deactivated at a high level (or VDD). Then, the PMOS transistor PM1 is turned off, and the sensing node SO charged with the precharge voltage Vprch is developed according to the level of the bit line BL.

At T2, a latch operation of the sensing latch SL for the sensing node SO will be performed. The control signal MON_S for connecting the sensing latch SL and the sensing node SO will transition to high level. The trip level controller 1325 provides a first level SOA_vfy during a verification read operation and a second level SOA_rd lower than the first level SOA_vfy during a data read operation as a control signal SOA to the gate of the NMOS transistor NM15. Then, the NMOS transistor NM15 is turned on and the NMOS transistor NM14 for grounding the latch LT is turned on by the develop voltage (Vdvl_On or Vdvl_Off) of the sensing node SO. The latch LT is tripped at T3 when the reset signal RST transitions to high level. The trip voltage of the sensing latch SL can be made different for the different operation modes by varying the level of the control signal SOA depending on the operation mode.

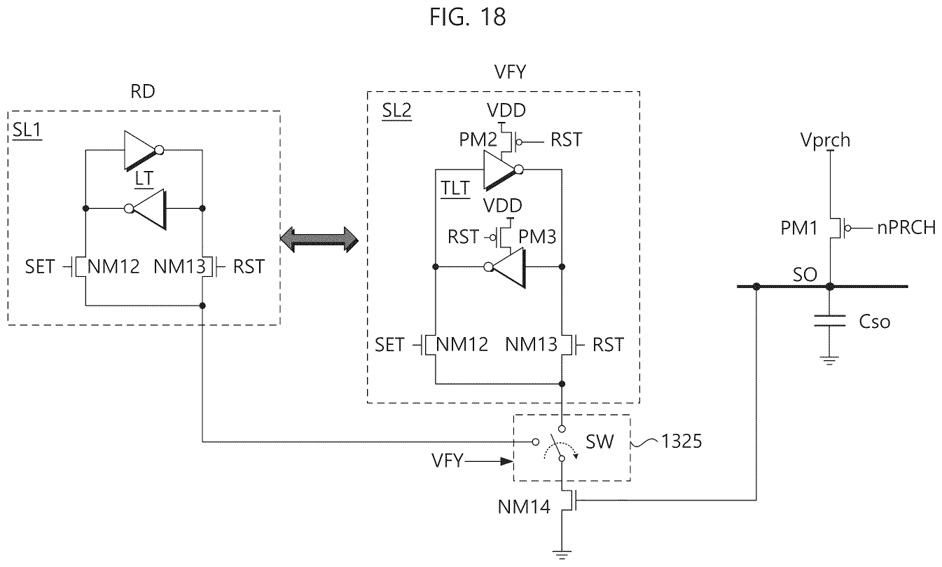

FIG. 18 is a circuit diagram showing another example of the trip level controller and sensing latch of FIG. 15. Referring to FIG. 18, the trip level controller 1325 selects one of the first sensing latch SL1 and the second sensing latch SL2 according to the read mode signal (VFY or RD). The development level of the sensing node SO may be latched by the selected sensing latch.

The trip level controller 1325 selects one of the first sensing latch SL1 and the second sensing latch SL2 according to the operation mode. For example, during a data read operation, the trip level controller 1325 may select the first sensing latch SL1 having a relatively high trip level. On the other hand, during a verification read operation, the trip level controller 1325 may select the second sensing latch SL2 having a relatively low trip level.

The first sensing latch SL1 may latch or initialize the voltage developed by the set or reset transistors NM12 and NM13 using the inverter-type latch LT. For example, since each inverter is composed of one PMOS transistor and one NMOS transistor, the latch of the developed voltage depends on the racing of these PMOS transistors and NMOS transistors. Accordingly, the trip level of the first sensing latch SL1 must be relatively high for racing with the PMOS transistor.

The second sensing latch SL2 may latch or initialize the voltage developed by the set or reset transistors NM12 and NM13 using the tri-state latch TLT. The tri-state latch TLT includes PMOS transistors PM2 and PM3 to block the PMOS transistor in the high section of the reset signal RST where the trip level latch occurs. Therefore, the trip level of the tri-state latch TLT depends entirely on the operation of the NMOS transistor of the inverter without racing in the latch section of the sensing node. As a result, the trip level of the second sensing latch SL2 is determined by the NMOS transistor of the inverter and is therefore relatively lower than that of the first sensing latch SL1.

Accordingly, the trip voltage of the sensing latch can be varied by selecting the first and second sensing latches SL1 and SL2, which have different trip level characteristics, according to the operation mode. Here, the first sensing latch SL1 and the second sensing latch SL2 may be configured as separate sensing latches as shown, but, in some implementations, one inverter-type latch LT can be changed into a tri-state latch TLT depending on the read mode.

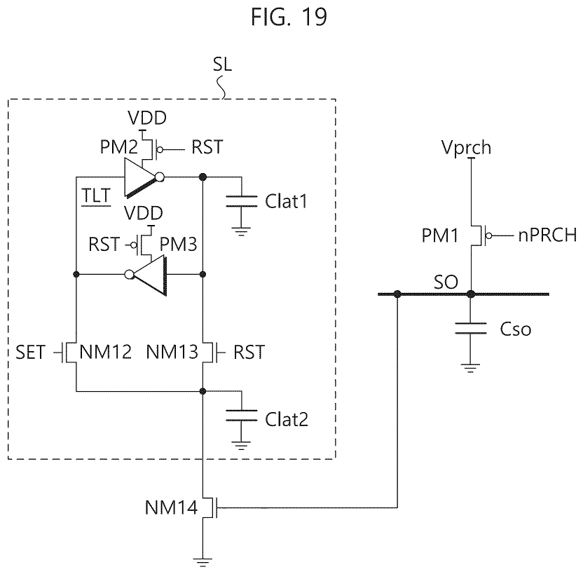

FIG. 19 is a circuit diagram showing another example of the trip level controller and sensing latch of FIG. 15. Referring to FIG. 19, depending on the read mode, the sensing latch SL may disconnect or connect the latch capacitors Clat1 and Clat2 to the tri-state latch TLT.

For example, in a verification read operation, the latch capacitors Clat1 and Clat2 may be separated from the tri-state latch TLT. By disconnecting the latch capacitors Clat1 and Clat2, the trip speed of the tri-state latch TLT increases. Increasing the trip speed can provide the effect of increasing the trip voltage. On the other hand, in a data read operation, the latch capacitors Clat1 and Clat2 may be connected to the tri-state latch TLT. The tripping speed of the tri-state latch TLT is reduced by connecting the latch capacitors Clat1 and Clat2. Reducing the trip speed can provide a lowering effect on the trip voltage.

The utilization and application of the above-described latch capacitors Clat1 and Clat2 may be changed or modified in various ways. For example, instead of connecting or disconnecting the latch capacitors Clat1 and Clat2, charging or discharging according to the read mode may be applied to provide a trip level adjustment effect of the sensing latch SL.

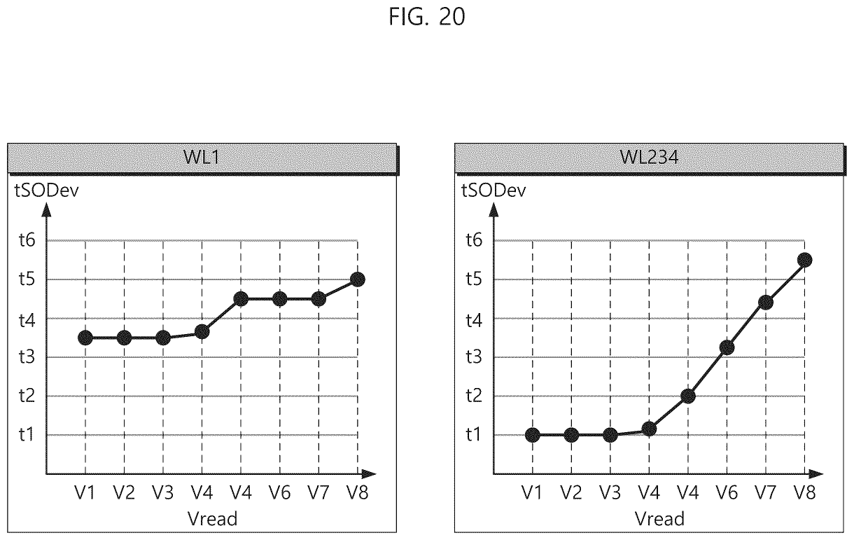

FIG. 20 is a graph showing the development time of the optimal sensing node according to the position of the word line. Referring to FIG. 20, it can be seen that the size of the optimal sensing current varies depending on the read pass voltage Vread for each word line WL1 and WL234.

It can be seen that, in addition to the differentiation of operations according to the read mode described above, it is possible to differentiate operations by position of the word line according to changes in the optimal characteristics of the page buffer or the sensing current for each position of the word line shown. For example, the level of the precharge voltage, the boosting or de-boosting level of the boosting node, the trip voltage Vtrip of the sensing latch may be applied differently for each position of the word line.

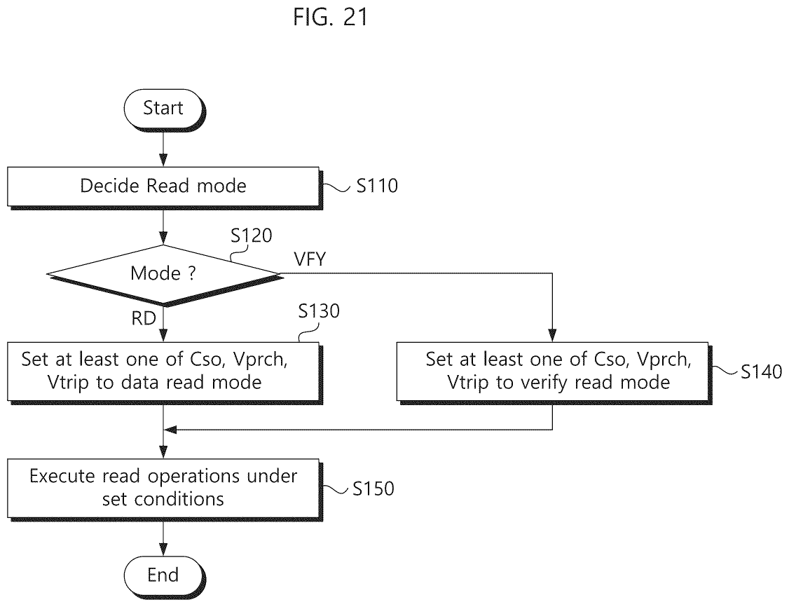

FIG. 21 is a flowchart showing the operating method of the non-volatile memory device according to some implementations. Referring to FIG. 21, the non-volatile memory device 1000 may perform separate data read operations and verification read operations of the page buffer circuit 1300 according to the read mode provided by the mode selector 1310 (see FIG. 5).

In step S110, the mode selector 1310 of the page buffer circuit 1300 determines whether the read mode to be executed is the data read mode or the verification read mode.

In step S120, the page buffer circuit 1300 performs an operation branch according to the read mode. If the read mode is data read mode RD, the procedure moves to step S130. On the other hand, if the read mode is verification read mode VFY, the procedure moves to step S140.

In step S130, the page buffer circuit 1300 sets the data read mode RD for at least one of the capacitance of the sensing node SO, the precharge level of the sensing node SO, and the trip level of the sensing latch SL.

In step S140, the page buffer circuit 1300 sets a verification read mode VFY for at least one of the capacitance of the sensing node SO, the precharge level of the sensing node SO, and the trip level of the sensing latch SL.

In step S150, the page buffer circuit 1300 executes a read operation according to at least one of the capacitance of the sensing node SO, the precharge level of the sensing node SO, and the trip levels of the sensing latch SL determined in step S130 or S140.

In the above, methods for separating the sensing current according to the read mode of the page buffer circuit 1300 were described. By using the page buffer circuit 1300, at least one of the capacitance of the sensing node SO, the precharge level, and the trip level of the sensing latch can be varied rather than adjusting the development time Tso_dev. Accordingly, in some implementations, data reliability of the non-volatile memory device 1000 can be improved without performance degradation caused by adjusting the development time of the sensing node SO.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

In addition to the above-described examples, the scope of the present disclosure includes design changes, modifications, and variations. Therefore, the scope of the present disclosure is not limited to the above-described examples, and should be defined at least by the following claims.

What is claimed is:

1. A method of operating a page buffer included in a non-volatile memory device, the method comprising:
determining a read mode;
setting at least one of a capacitance of a sensing node of the page buffer, a precharge level of the sensing node, or a trip level of a sensing latch of the page buffer, based on the read mode; and
performing a program operation or a read operation on a cell using the set at least one of the capacitance, the precharge level, or the trip level.

2. The method of claim 1, wherein the read mode comprises a verification read mode for writing data into the selected cell or a data read mode for reading data stored in the selected cell.

3. The method of claim 2, wherein the read mode comprises the verification read mode, and
wherein setting the at least one of the capacitance, the precharge level, or the trip level comprises:
connecting a verification capacitor to the sensing node to increase the capacitance of the sensing node in the verification read mode.

4. The method of claim 3, wherein connecting the verification capacitor comprises biasing a metal line or active area that is not used in the verification read mode.

5. The method of claim 2, wherein the read mode comprises the data read mode, and
wherein setting the at least one of the capacitance, the precharge level, or the trip level comprises:
disconnecting a verification capacitor from the sensing node.

6. The method of claim 2, wherein the precharge level of the sensing node comprises one of a first precharge voltage or a second precharge voltage that is lower than the first precharge voltage.

7. The method of claim 6, wherein setting the at least one of the capacitance, the precharge level, or the trip level comprises:
selecting the first precharge voltage based on the read mode comprising the verification read mode, or
selecting the second precharge voltage based on the read mode comprising the data read mode.

8. The method of claim 6, comprising generating the first precharge voltage or the second precharge voltage through voltage clamping or voltage boosting.

9. The method of claim 1, wherein setting the at least one of the capacitance, the precharge level, or the trip level comprises varying the trip level of the sensing latch by transmitting a develop voltage of the sensing node to the sensing latch at a varying clamping level based on the read mode.

10. The method of claim 1, wherein setting the at least one of the capacitance, the precharge level, or the trip level comprises varying the trip level by selectively applying an inverter type latch or a tri-state latch type latch to the sensing latch based on the read mode.

11. The method of claim 2, wherein setting the at least one of the capacitance, the precharge level, or the trip level comprises varying the trip level by connecting or disconnecting a latch capacitor to or from the sensing latch based on the read mode.

12. A non-volatile memory device, comprising:
a cell array including a cell string connected to a bit line;
a row decoder configured to select a memory cell of the cell string in response to an address;
a page buffer including a sensing node and a sensing latch for sensing the selected memory cell through the bit line; and
a control circuit configured to control a sensing operation of the page buffer based on a read command or a program command,
wherein the page buffer is configured to vary at least one of a capacitance of the sensing node, a precharge level of the sensing node, or a trip level of the sensing latch based on an operation mode.

13. The device of claim 12, wherein the operation mode includes a verification read mode for writing data into the selected memory cell or a data read mode for reading data stored in the selected memory cell, and
wherein the page buffer includes a mode selector configured to identify the operation mode.

14. The device of claim 13, wherein the page buffer includes a sensing node capacitance variation circuit configured to, for the verification read mode, connect a verification capacitor to a capacitance of the sensing node.

15. The device of claim 14, wherein the sensing node capacitance variation circuit is configured to, for the data read mode, disconnect the verification capacitor from the sensing node.

16. The device of claim 13, wherein the page buffer includes a precharge level variation circuit configured to, based on the operation mode, select one of a first precharge voltage or a second precharge voltage lower than the first precharge voltage as the precharge level.

17. The device of claim 13, wherein the page buffer includes a trip level controller configured to vary the trip level of the sensing latch based on the operation mode.

18. The device of claim 12, wherein the page buffer is configured to determine the at least one of the capacitance of the sensing node, the precharge level of the sensing node, or the trip level of the sensing latch based on at least one of a location, an operating temperature, or a wear level of the selected memory cell.

19. A method of operating a non-volatile memory device, the method comprising:
precharging a sensing node of a page buffer;
developing the precharged sensing node based on a level of a selected bit line; and
setting a sensing latch based on a development level of the developed sensing node,
wherein, in the precharging of the sensing node, a precharge voltage of the sensing node or a capacitance of the sensing node is set differently between a verification read operation and a data read operation.

20. The method of claim 19, wherein, in the setting of the sensing latch, a trip level of the sensing latch is set differently between the verification read operation and the data read operation.
